(19) United States
(12) Patent Application Publication
(10) Pub. No.: US 2010/0103744 A1
(43) Pub. Date: Apr. 29, 2010

(54) Non-volatile memory device and method of driving the same

(76) Inventors: Seung-jin Yang, Seoul (KR); Jeong-uk Han, Suwon-si (KR); Yong-tae Kim, Yongin-si (KR); Yong-suk Choi, Hwaseong-si (KR); Bae-seong Kwon, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/588,680

(22) Filed: Oct. 23, 2009

(30) Foreign Application Priority Data
Oct. 24, 2008 (KR) 10-2008-0104984

(51) Int. Cl. G11C 16/04; G11C 11/34

(52) U.S. Cl. 365/185.26; 365/185.18; 365/184; 257/324

(57) ABSTRACT

A non-volatile memory device includes a memory cell array with a plurality of unit memory cells arranged in a matrix pattern, each of the unit memory cells having first and second non-volatile memory transistors sharing a common source, and a selection transistor connected between the common source and one of the first and second non-volatile memory transistors, a first word line coupled to control gates of the first non-volatile memory transistors arranged in a column direction of the memory cell array, a second word line coupled to control gates of the second non-volatile memory transistors arranged in the column direction of the memory cell array, a selection line coupled to gates of the selected transistors arranged in the column direction of the memory cell array, and at least one bit line coupled to drains of the first and second non-volatile memory transistors.

### BACKGROUND

1. Field

Example embodiments relate to a semiconductor device and a method of operating the semiconductor device, and more particularly, to a non-volatile memory device and a method of operating the non-volatile memory device.

2. Description of the Related Art

Various digital information devices, e.g., personal information terminals, mobile phones, set-top boxes, etc., may be made thin and light, and may include a system-on-chip (SOC). The SOC may include two or more semiconductor chips integrated into a single chip. The SOC technology may not only reduce the manufacturing cost of a system, but may also enable easy design, low power operation, and miniaturization of the system. For example, the SOC may be used in smart cards or subscriber identification module (SIM) cards which may be used for communications, financial trades, health insurance cards, and electronic business trades.

For example, a non-volatile memory area installed in a smart card may include a data flash array area for storing firmware provided by a product supplier and a program flash array area for storing user data. The conventional data flash array area and program flash array area may be physically separated from each other in the non-volatile memory area of the smart card, i.e., in the chip. These array areas may include non-volatile memory devices capable of storing information after power is off, e.g., electrically erasable programmable read only memories (EEPROMs).

However, when the conventional data flash array area and program flash array area are separated from each other, separate peripheral circuits, e.g., a decoder and a sense amplifier, may be needed for the separate flash areas. Therefore, scaling down of the non-volatile memory area may be difficult and resources may be wasted.

### SUMMARY

Embodiments are therefore directed to a non-volatile memory device and a method of operating the non-volatile memory device, which substantially overcome one or more of the problems due to the limitations and disadvantages of the related art.

It is therefore a feature of an embodiment to provide a non-volatile memory device with a data flash array area and a program flash array area integrated into a unified memory area on a semiconductor substrate so that high integration may be possible and efficient use of peripheral circuits and reliability of devices may be obtained.

It is therefore another feature of an embodiment to provide a method of driving a non-volatile memory device having one or more of the above features.

At least one of the above and other features and advantages may be realized by providing a non-volatile memory device. The non-volatile memory device may include a memory cell array of a plurality of unit memory cells arranged in form of a matrix of rows and columns, each of the unit memory cells including first and second non-volatile memory transistors sharing a common source, and a selection transistor connected between the common source and any one of the first and second non-volatile memory transistors.

Control gates of the first non-volatile memory transistors arranged in a column direction of the memory cell array may be coupled to a first word line, control gates of the second non-volatile memory transistors arranged in the column direction of the memory cell array may be coupled to a second word line and gates of the selected transistors arranged in the column direction of the memory cell array may be coupled to a selection line. Drains of the first and second non-volatile memory transistor may be coupled to at least one bit line.

The first and second non-volatile memory transistors may be programmed in different ways from each other. In example embodiments, any one of the first and second non-volatile memory transistors may be a NOR type transistor and the other one may be a NAND type transistor. In example embodiments, the selection transistor may be connected between the NAND type transistor and the common source. A source/drain terminal of the one of the first and second non-volatile memory transistor, which is connected to the selection transistor, may be floated.

In example embodiments, at least one of the first and second non-volatile memory transistors may include a first insulation layer, a charge storage layer and a second insulation layer. The first insulation layer, the charge storage layer and the second insulation layer may be sequentially stacked between a semiconductor substrate on which the memory cell array is formed and the control gates of the first and second non-volatile memory transistors.

The charge storage layer may include a floating conductive layer or a charge trap type insulation layer. At least one of the first and second insulation layers may include a high dielectric thin layer.

The non-volatile memory device may be applied to at least one of SIM, smart card, and electronic passport.

At least one of the above and other features and advantages may also be realized by providing a method of driving a non-volatile memory device including a memory cell array in which a plurality of unit memory cells are arranged in form of a matrix of rows and columns, each of the unit memory cells comprising first and second non-volatile memory transistors sharing a common source and a selection transistor connected between the common source and any one of the first and second non-volatile memory transistors. The method may include selecting at least one of the first and second non-volatile memory transistors and programming the selected at least one of non-volatile memory transistor; selecting at least one of the first and second non-volatile memory transistors and reading the selected at least one of non-volatile memory transistors; and selecting the at least one of the first and second non-volatile memory transistors and erasing the selected at least of first and second non-volatile memory transistors.

Any one of the first and second non-volatile memory transistors may be operated in a NOR type method and the other one may be operated in a NAND type method. The programming of the selected non-volatile memory transistor may include applying a program voltage to a word line coupled to a control gate of the selected non-volatile memory transistor of the first and second non-volatile memory transistors that are continuously arranged in a column direction of the memory cell array; and applying a turn-off voltage to a selection line coupled to gate of selection transistor connected to the selected non-volatile memory transistor of the selection transistors that are continuously arranged in the column direction of the memory cell array.

The erasing of the selected non-volatile memory transistor may includes applying an erasing voltage to a word line coupled to a control gate of the selected non-volatile memory transistor of the first and second non-volatile memory transistors that are continuously arranged in a column direction of the memory cell array; and applying a voltage to compensate the erasing voltage to a bit line coupled to drains of non-selected non-volatile memory transistors coupled to the word line. The erasing of the selected non-volatile memory transistor may be performed by block or page.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a circuit diagram of a unit memory cell of a non-volatile memory device according to an example embodiment;

FIG. 2 illustrates a cross-sectional view of a structure of the unit memory cell in FIG. 1; and

FIG. 3 illustrates a circuit diagram of a non-volatile memory device according to an example embodiment.

### DETAILED DESCRIPTION

Korean Patent Application No. 10-2008-0104984, filed on Oct. 24, 2008, in the Korean Intellectual Property Office, and entitled: “Non-Volatile Memory Device and Method of Driving the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer, element, or substrate, it can be directly on the other layer, element or substrate, or intervening layers and/or elements may also be present. In addition, it will also be understood that when a layer or element is referred to as being “between” two layers or elements, it can be the only layer or element between the two layers or element, or one or more intervening layers and/or elements may also be present. Like reference numerals refer to like elements throughout. As used in the present specification, the term “and/or” includes any one of listed items and all of at least one combination of the items.

The terms used in the present specification are used for explaining a specific exemplary embodiment, not limiting the present example embodiment. Thus, the expression of singularity in the present specification includes the expression of plurality unless clearly specified otherwise in context. Also, the terms such as “comprise” and/or “comprising” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In the present specification, the terms such as “first” and “second” are used herein merely to describe a variety of members, parts, areas, layers, and/or portions, but the constituent elements are not limited by the terms. It is obvious that the members, parts, areas, layers, and/or portions are not limited by the terms. The terms are used only for the purpose of distinguishing one constituent element from another constituent element. Thus, without departing from the right scope of the present example embodiment, a first member, part, area, layer, or portion may refer to a second member, part, area, layer, or portion.

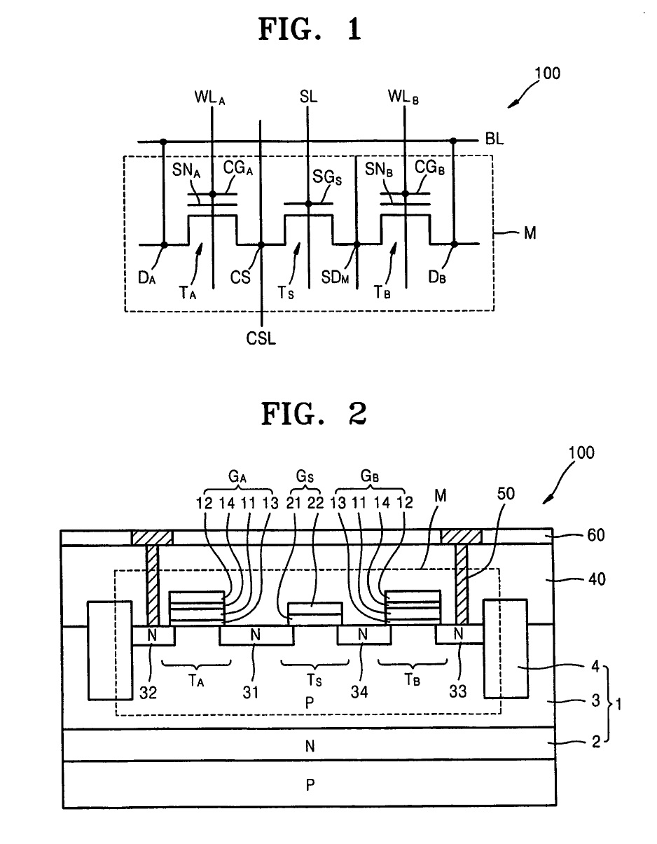

FIG. 1 illustrates a circuit diagram of a unit memory cell M of a non-volatile memory device 100 according to exemplary embodiments.

Referring to FIG. 1, the unit memory cell M of the non-volatile memory device 100 may include first and second non-volatile memory transistors T_{A} and T_{B}. A common source CS may be shared by the first and second non-volatile memory transistors T_{A} and T_{B} and may be coupled to a common source line CSL.

A selection transistor T_{S} may be connected between the common source CS and any one of the first and second non-volatile memory transistors T_{A} and T_{B}. The selection transistor T_{S} may function as a switching device to selectively access any one of the first and second non-volatile memory transistors T_{A} and T_{B}. For example, the selection transistor T_{S} may be a metal-oxide semiconductor field-effect transistor (MOSFET).

For example, the selection transistor T_{S} may be connected between the common source CS and the second non-volatile memory transistor T_{B}, as illustrated in FIG. 1. A source/drain terminal SD_{M}, where the selection transistor T_{S} and the second non-volatile memory transistor T_{B} are connected, may be floating. A selection gate SG_{S} of the selection transistor T_{S} may be coupled to a selection line SL. The selection transistor T_{S} between the first and second non-volatile memory transistors T_{A} and T_{B} may prevent or substantially minimize unwanted electron/hole injection, e.g., due to voltage difference between their sources/drains, in unselected non-volatile memory transistors.

In contrast, without the selection transistor T_{S} as described above, even when an erasing voltage is not applied to a control gate of each of the non-volatile memory transistors, electrons may generally be injected from a charge storage layer to a drain area, or holes, e.g., generated by an impact ionization process in a semiconductor substrate, may be injected into the charge storage layer through a tunneling insulation layer by a voltage difference, e.g., about 5 V, between the drain and source. Such injections may be frequently generated as the thickness of the tunneling insulation layer decreases, thereby causing malfunction, e.g., unwanted programming or data erasing, in an unselected non-volatile memory transistor.

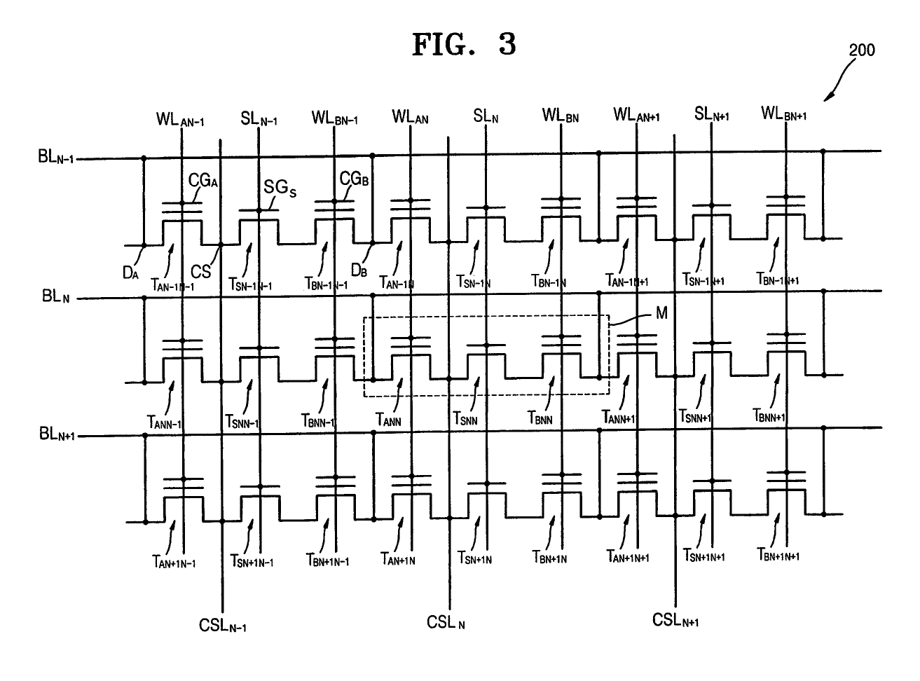

However, as illustrated in FIG. 1, when the selection transistor T_{S} is arranged between the first and second non-volatile memory transistors T_{A} and T_{B}, the selection transistor T_{S} may be turned-off in order to prevent unwanted injections of electrons and/or holes in unselected memory transistor. For example, even when a high voltage is applied to the common source CS for the program operation of the first non-volatile memory transistor T_{A}, the selection transistor T_{S} may be turned-off, so no injections may occur in the unselected second non-volatile memory transistors T_{B}, thereby preventing malfunction, e.g., unwanted programming, in the second non-volatile memory transistors T_{B}. When voltage is applied for the program operation of the second non-volatile memory transistor T_{B}, the selection transistor T_{S} may be turned-off to prevent malfunction in the first non-volatile memory transistors T_{A}, as will be described in more detail below with reference to FIG. 3.

The first and second non-volatile memory transistors T_{A} and T_{B} may include first and second storage nodes SN_{A} and SN_{B}, respectively, and first and second control gates CG_{A} and CG_{B}, respectively, for controlling the first and second storage nodes SN_{A} and SN_{B}. The first and second control gates CG_{A} and CG_{B} may be coupled respectively to first and second word lines WL_{A} and WL_{B}. The first and second non-volatile memory transistors T_{A} and T_{B} may be operated in different modes. For example, the first non-volatile memory transistor T_{A} may be operated in a NOR flash mode, while the second non-volatile memory transistor T_{B} may be operated in a NAND flash mode. In another example, the first non-volatile memory transistor T_{A} may be operated in the NAND flash mode, while the second non-volatile memory transistor T_{B} may be operated in the NOR flash mode.

In particular, NOR flash architecture may exhibit a fast write speed but may require a larger area and high power per unit memory cell. Thus, the NOR flash architecture may be generally used for storing firmware, because the firmware is not subject to frequent update thereof. The NAND flash architecture may enable higher density formation with less power, e.g., as compared to the NOR flash architecture. Thus, the NAND flash architecture may be generally used for storing user data, because the user data has a high capacity and is subject to frequent update thereof during device operation.

Drains D_{A} and D_{B} of the first and second non-volatile memory transistors T_{A} and T_{B} may be coupled to a bit line BL. As illustrated in FIG. 1, although the first and second non-volatile memory transistors T_{A} and T_{B} share a single bit line BL, example embodiments are not limited thereto. For example, the first and second non-volatile memory transistors T_{A} and T_{B} may be coupled to different bit lines.

FIG. 2 illustrates a cross-sectional view of a structure of the unit memory cell M of FIG. 1 formed on a semiconductor substrate 1.

Referring to FIG. 2, the semiconductor substrate 1, in which the non-volatile memory device 100 is formed, may be, e.g., a silicon monocrystal substrate. However, example embodiments are not limited thereto and the semiconductor substrate 1 may be, e.g., a silicon-on-insulator (SOI) substrate. Isolation layers 4 for defining an active area, in which one or more unit memory cells M are formed, may be formed in the semiconductor substrate 1. In example embodiments, the semiconductor substrate 1 may be a first conductive type, e.g., a P type. A deep well region 2 of a second conductive type, e.g., a deep N type well region, may be formed in the semiconductor substrate 1 by an ion injection process or an impurity diffusion process. A well 3 of the first conductive type, e.g., a P-type well, for the unit memory cell M may be formed in the deep N type well region 2.

The respective channels of the first and second non-volatile memory transistors T_{A} and T_{B} and the selection transistor T_{S} may be provided by at least portions of a surface area of the semiconductor substrate 1. The common source CS, the drains D_{A} and D_{B}, and the source/drain terminal SD_{M}, to which the selection transistor T_{S} and the second non-volatile memory transistor T_{B} are connected, may be respectively provided by impurity regions 31, 32, 33, and 34 formed in the semiconductor substrate 1. The impurity regions 31, 32, 33, and 34 may be of the second conductive type, e.g., an N type. The second conductive type may be opposed to the first conductive type of the semiconductor substrate 1.

The impurity regions 31, 32, 33, and 34 may be simultaneously formed by injecting ions into the P type well 3 using, as a mask, gate stacks G_{A}, G_{B}, and G_{S} which will be described later. Alternatively, at least one of the impurity areas 31, 32, 33, and 34 may be formed by separate ion injection processes, or prior to the formation of the gate stacks G_{A}, G_{B}, and G_{S}.

The gate stacks G_{A}, G_{B}, and G_{S} of the first and second non-volatile memory transistors T_{A} and T_{B} and the selection transistor T_{S} may be formed on the semiconductor substrate 1. For the first and second storage nodes SN_{A} and SN_{B} illustrated in FIG. 1, each of the gate stacks G_{A} and G_{B} may include a charge storage layer 11. For the first and second control gates CG_{A} and CG_{B} illustrated in FIG. 1, each of the gate stacks G_{A} and G_{B} may include a control gate electrode layer 12 for controlling the charge storage layer 11. The control gate electrodes 12 may be respectively coupled to the word lines WL_{A} and WL_{B} of FIG. 1. In example embodiments, the control gate electrode layer 12 may form a part of the word lines WL_{A} and WL_{B}.

The charge storage layer 11 of each of the gate stacks G_{A} and G_{B} may be a floating conductive layer or a charge trap type dielectric layer. The floating conductive layer may include, e.g., one or more of a highly doped polysilicon layer, a metal layer, a conductive metal nitride layer, and a conductive metal oxide layer. The charge trap type dielectric layer may include, e.g., one or more of a silicon nitride layer, a metal nitride layer, and a metal oxide layer.

The charge storage layer 11 for the above-described storage node is exemplary and the example embodiments are not limited thereto. For example, the charge storage layer 11 may be formed of multiple layers by depositing at least two layers. An additional layer to improve programming and/or erasing performance, e.g., a nano crystal layer, may be formed in the layers or at an interface between the layers. Also, the charge storage layer 11 of each of the first and second non-volatile memory transistors T_{A} and T_{B} may be formed in different structures based on the difference in programming and erasing mechanisms which will be described later.

In example embodiments, an insulation layer 13 may be formed between the semiconductor substrate 1 and the charge storage layer 11, and an insulation layer 14 may be formed between the charge storage layer 11 and the control gate electrode layer 12. The insulation layers 13 and 14 may function as a tunneling insulation layer or a blocking insulation layer. The insulation layers 13 and 14 may include, e.g., a silicon oxide layer and/or a high dielectric thin film having a dielectric constant higher than that of the silicon oxide layer. Examples of the high dielectric thin film may include one or more of a silicon nitride layer (SiNx), a tantalum oxide layer (TaOx), a hafnium oxide layer (HfOx), an aluminum oxide layer (AlOx), and a zinc oxide layer (ZnOx).

The gate stack G_{S} of the selection transistor T_{S} may include a gate insulation layer 21 and a gate electrode layer 22 which may be sequentially deposited on the semiconductor substrate 1. In the embodiment of FIG. 2, the selection transistor T_{S} may be an N type FET. However, the selection transistor T_{S} may be also a P type FET. Furthermore, the selection transistor T_{S} may be any other suitable MOS transistor capable of switching in a high voltage region. The gate electrode layer 22 of the selection transistor T_{S}, i.e., corresponding to the selection gate SG_{S} in FIG. 1, may be coupled to the selection line SL. The gate electrode layer 22 may also constitute a part of the selection line SL.

After the first and second non-volatile memory transistors T_{A} and T_{B} and the selection transistor T_{S} are completely formed, an interlayer insulation layer 40 may be formed on the substrate 1 to cover and protect the transistors. The interlayer insulation layer 40 may be, e.g., a silicon oxide layer formed by plasma enhanced chemical vapor deposition (PECVD). Then, a bit line conductive layer 60, i.e., corresponding to the bit line BL in FIG. 1, may be formed on the interlayer insulation layer 40. For example, the bit line conductive layer 60 may be connected to each of the drain regions 32 and 33 of the first and second non-volatile memory transistors T_{A} and T_{B} via a contact plug 50 that penetrates the interlayer insulation layer 40. In another example, as described previously with reference to FIG. 1, the drain regions 32 and 33 of the first and second non-volatile memory transistors T_{A} and T_{B} may be connected respectively to different bit line conductive layers.

In FIG. 2, although the first and second non-volatile memory transistors T_{A} and T_{B}, as well as the selection transistor T_{S}, are described as having flat structures, other suitable structures and configurations of transistors are included within the scope of the inventive concept. For example, one or more of the first and second non-volatile memory transistors T_{A} and T_{B}, as well as the selection transistor T_{S}, may have a channel of 3-dimensional structure, e.g., a recess channel or a pin type channel.

FIG. 3 illustrates a circuit diagram of a non-volatile memory device 200 according to exemplary embodiments. Referring to FIG. 3, the non-volatile memory device 200 may include a plurality of unit memory cells arranged in a matrix pattern, i.e., in a form of rows and columns. Each of the unit memory cells in the non-volatile memory device 200 may be the unit memory cell M of the non-volatile memory device 100 described previously with reference to FIG. 1. The non-volatile memory device 200 may include any suitable number of unit memory cells M, e.g., at least two unit memory cells M.

A plurality of first control gates CG_{A} of the unit memory cells M that are continuously arranged in a column direction, i.e., a direction substantially parallel to a direction of a gate line, may be coupled to a same gate line. A plurality of first control gates CG_{A} of the unit memory cells M that are continuously arranged in a row direction, i.e., a direction substantially parallel to a direction of a bit line, may be coupled to respective first gate lines WL_{AN-1}, WL_{AN}, WL_{AN+1}. Similarly, a plurality of second control gates CG_{B} of the unit memory cells M that are continuously arranged in the column direction may be coupled to a same gate line, i.e., a gate line different than the gate line coupled to the plurality of first control gates CG_{A} arranged in a column direction, while a plurality of second control gates CG_{B} of the unit memory cells M that are continuously arranged in the row direction may be coupled to respective second gate lines WL_{BN-1}, WL_{BN}, WL_{BN+1}. Similarly, the selection gates SG_{S} of the unit memory cells M that are continuously arranged in the column direction may be coupled to a same selection line, while the selection gates SG_{S} of the unit memory cells M that are continuously arranged in the row direction may be respectively coupled to a plurality of selection lines SL_{N-1}, SL_{N}, SL_{N+1}.

Also, the common sources CS of the unit memory cells M that are continuously arranged in the row direction may be respectively coupled to a plurality of common source lines CSL_{N-1}, CSL_{N}, CSL_{N+1}. In example embodiments, the common source lines CSL_{N-1}, CSL_{N}, CSL_{N+1} may be commonly connected so as to be operated by a signal electric potential. As illustrated in FIG. 3, the drains D_{A} and D_{B} of the unit memory cells M that are continuously arranged in a row direction may be coupled to a same bit line or to different bit lines, as described previously with reference to FIG. 1. The drains D_{A} and D_{B} of the unit memory cells M that are continuously arranged in a column direction may be respectively coupled to a plurality of bit lines BL_{N-1}, BL_{N}, BL_{N+1}, as illustrated in FIG. 3

Referring to FIG. 3, an operation method of the above-described non-volatile memory device 200 is described below. For example, the programming, erasing, and reading operation of the unit memory cell M indicated by a dotted line among the plurality unit memory cells arranged in a row and column matrix format are described. For convenience of explanation, it is assumed that a plurality of first non-volatile memory transistors T_{AN-1N-1}, . . . , T_{ANN}, . . . , T_{AN+1N+1} are operated by a NOR flash operation method and a plurality of second non-volatile memory transistors T_{BN-1N-1}, . . . , T_{BNN}, . . . , T_{BN+1N+1} are operated by a NAND flash operation method. Also, it is assumed that the first and second non-volatile memory transistors T_{AN-1N-1}, . . . , T_{ANN}, . . . , T_{AN+1N+1}; T_{BN-1N-1}, . . . , T_{BNN}, . . . , T_{BN+1N+1} and the selection transistors T_{SN-1N-1}, . . . , T_{SNN}, . . . , T_{SN+1N+1} are all N type transistors. Other types and configurations of transistors in the non-volatile memory device 200, as discussed previously with reference to FIG. 1, are within the scope of the inventive concept.

Also, it is assumed that for programming by a hot carrier injection method, a voltage difference between the common source CS and the drain D_{A} is about 4.5 V, and an operation voltage applied to the control gate CG_{A} and a bulk region of the semiconductor substrate 1 is about 11 V. Also, it is assumed that for programming by a Fowler-Nordheim tunneling method, a voltage difference between the source and the drain is about 0 V or more, and an operation voltage applied to the control gate CG_{B} and the bulk region of the semiconductor substrate 1 is about 16 V.

Programming Operation

A programming operation of the first non-volatile memory transistor T_{ANN} of a selected unit memory cell M may be performed by a hot carrier injection operation, so the first non-volatile memory transistor T_{ANN} may secure a fast program speed. However, since the programming by the hot carrier injection method requires a high operation current, a sufficient life span may be difficult to obtain for the first non-volatile memory transistor T_{ANN}. Accordingly, the first non-volatile memory transistors T_{AN-1N-1}, . . . , T_{ANN}, . . . , T_{AN+1N+1} may be used for storing command codes that tend not to be frequently updated, e.g., firmware.

Voltages applied to lines during the hot carrier injection programming of the first non-volatile memory transistor T_{ANN} are shown in Table 1. A back bias voltage VB applied to the bulk region of the semiconductor substrate 1 in which a channel is formed may be about 0 V or may be grounded. However, this is exemplary and the back bias voltage VB may be a negative voltage to increase an efficiency of the programming of the first memory cell.

TABLE 1

| BL_{N-1} | CSL_{N-1} | WL_{AN-1} | SL_{N-1} | WL_{BN-1} |
|---|---|---|---|---|
| V_{cc} | 0 V | 0 V | 0 V | — |
| BL_{N} | CSL_{N} | WL_{AN} | SL_{N} | WL_{BN} |
| 0.5 V | 5 V | V_{P1} (11 V) | Ground | 0 V or 5 V |
| BL_{N+1} | CSL_{N+1} | WL_{AN+1} | SL_{N+1} | WL_{BN+1} |
| V_{cc} | 0 V | 0 V | 0 V | — |

Referring to Table 1, for example, about 5 V may be applied to the common source line CSL_{N} and about 0.5 V may be applied to the bit line BL_{N}. In particular, in order to prevent generation of a punch-through in the selected first memory transistor T_{ANN}, e.g., due to a high voltage applied to the common source CS, a voltage slightly higher than a potential of the grounded semiconductor substrate 1 may be applied to the bit line BL_{N}, e.g., about 0.5 V. A program voltage V_{P1}, e.g., about 11 V, may be applied to the word line WL_{AN}. The selection line SL_{N} may be grounded to set the selection transistor T_{SNN} in an OFF state.

For non-selected unit memory cells, the common source lines CSL_{N-1} and CSL_{N+1} coupled to the non-selected unit memory cells may be floated or grounded. To prevent hot carrier injection in adjacent non-selected first memory transistors T_{AN-1N} and T_{AN+1N} by the voltage applied to the selected word line WL_{AN} and the common source line CSL_{N}, a voltage V_{CC}, e.g., about 1.2 V to about 1.6 V, may be applied to the bit lines BL_{N-1} and BL_{N+1}. The voltage V_{CC} may be slightly higher than the voltage applied to the selected bit line BL_{N}, e.g., about 0.5 V. Also, a predetermined voltage, e.g., about 5 V, that does not generate programming by tunneling may be applied to the word lines WL_{AN-1}, WL_{BN-1}, WL_{BN}, WL_{AN+1}, and WL_{BN+1}. A voltage of about 0 V may be applied to the selection lines SL_{N-1} and SL_{N+1} to turn the selection transistor T_{SNN} off.

Next, the programming operation of the second non-volatile memory transistor T_{BNN} of the selected unit memory cells M will be described. The programming of the second non-volatile memory transistor T_{BNN} may be performed by the Fowler-Nordheim tunneling operation, so operation at a low current may be possible and a sufficient life span may be obtained for the second non-volatile memory transistor T_{BNN}. Thus, information stored in the second non-volatile memory transistor T_{BNN} may be user data that requires frequent update.

Voltages applied to the respective lines during Fowler-Nordheim tunneling programming of the second non-volatile memory transistor T_{BNN} are shown in Table 2. It is assumed that the back bias voltage VB applied to the bulk of the semiconductor substrate 1 in which the channel region is formed may be a negative value, e.g., about (−5) V. However, the applied voltages are exemplary and the example embodiments are not limited thereto.

TABLE 2

| BL_{N-1} | CSL_{N-1} | WL_{AN-1} | SL_{N-1} | WL_{BN-1} |
|---|---|---|---|---|
| 0 V | Ground | 0 V | Ground | Ground |
| BL_{N} | CSL_{N} | WL_{AN} | SL_{N} | WL_{BN} |
| −5 V | Floating | −5 V | −5 V | V_{P2} (11 V) |
| BL_{N+1} | CSL_{N+1} | WL_{AN+1} | SL_{N+1} | WL_{BN+1} |
| V_{cc} | 0 V | 0 V | Ground | Ground |

Referring to Table 2, the common source line CSL_{N} may be floated and, e.g., about (−5) V, may be applied to the bit line BL_{N}. A program voltage V_{P2}, e.g., about 11 V, may be applied to the word line WL_{BN}. To prevent erroneous programming of the adjacent memory cell transistors T_{ANN} by the program voltage V_{P2} applied to the selected second non-volatile memory transistor T_{BNN}, a voltage of about (−5) V may be applied to the selection line SL_{N} to turn off the selection transistor T_{SNN}.

For non-selected unit memory cells, the common source lines CSL_{N-1} and CSL_{N+1} coupled to the non-selected unit memory cells may be grounded. To prevent erroneous Fowler-Nordheim tunneling program by the selected word line WL_{AN}, a voltage, e.g., about 0 V, that is higher than the voltage applied to the selected bit line BL_{N}, e.g., about (−5) V, may be applied to the bit lines BL_{N-1} and BL_{N+1}. Also, the word lines WL_{AN-1}, WL_{BN-1}, WL_{AN}, WL_{AN+1}, and WL_{BN+1} and the selection lines SL_{N-1} and SL_{N+1} may be grounded. In example embodiments, a voltage of about (−5) V may be applied to the word line WL_{AN} to prevent erroneous programming of the adjacent first non-volatile memory transistor.

Erasing Operation

The erasing operation of the non-volatile memory device 200 in FIG. 3 is described below. For example, the erasing operation of the unit memory cell M indicated by the dotted line among the unit memory cells arranged in the row and column matrix format is described.

First, the erasing operation of the first non-volatile memory transistor T_{ANN} of the selected unit memory cell M is described in detail. The erasing of the first non-volatile memory transistor T_{ANN} may be performed by the Fowler-Nordheim tunneling method. The back bias voltage VB applied to the bulk region of the semiconductor substrate 1 may be about 11 V. The voltages applied to respective lines in the non-volatile memory device 200 are shown in Table 3. However, the applied voltages are exemplary and example embodiments are not limited thereto.

TABLE 3

| BL_{N-1} | CSL_{N-1} | WL_{AN-1} | SL_{N-1} | WL_{BN-1} |
|---|---|---|---|---|
| 5 V | Floating | — | — | — |
| BL_{N} | CSL_{N} | WL_{AN} | SL_{N} | WL_{BN} |
| Floating | Floating | −5 V | 5 V | 5 V |
| BL_{N+1} | CSL_{N+1} | WL_{AN+1} | SL_{N+1} | WL_{BN+1} |
| 5 V | Floating | — | — | — |

Referring to Table 3, both of the common source line CSL_{N} and the bit line BL_{N} may be floated and an erasing voltage, e.g., about (−5) V, may be applied to the word line WL_{AN}. Since the gate insulation layer of the selection transistor T_{SNN} may be damaged when a voltage difference between the back bias voltage VB and the selection line SL_{N} is large, a voltage, e.g., of about 5 V, may be applied to the selection line SL_{N}.

For non-selected unit memory cells, the common source lines CSL_{N-1} and CSL_{N+1} coupled to the non-selected unit memory cells may be floated. A voltage, e.g., about 5 V, may be applied to the bit lines BL_{N-1} and BL_{N+1}. Also, to prevent an erroneous erasing operation by the Fowler-Nordheim tunneling, a voltage, e.g., about 5 V, may be applied to the word lines WL_{AN-1}, WL_{BN-1}, WL_{BN}, WL_{AN+1}, and WL_{BN+1}. A voltage of about (−5) V may be applied to the selection lines SL_{N-1} and SL_{N+1} to prevent the gate insulation layer from being damaged as described above.

In example embodiments, the first non-volatile memory transistors T_{AN-1N-1}, . . . , T_{ANN}, . . . , T_{AN+1N+1} may be erased by block. For example, when an erasing voltage of about (−5) V is applied to the word lines WL_{AN-1}, WL_{BN-1}, and WL_{BN} connected to the first non-volatile memory transistors T_{AN-1N-1}, . . . , T_{ANN}, . . . , T_{AN+1N+1}, the first non-volatile memory transistors T_{AN-1N-1}, . . . , T_{ANN}, . . . , T_{AN+1N+1}, sharing one well, may be erased simultaneously. Also, in another embodiment, the first non-volatile memory transistors T_{AN-1N-1}, . . . , T_{ANN}, . . . , T_{AN+1N+1} may be erased by page, i.e., by word line. For example, by applying the erasing voltage, e.g., about (−5) V, only to the selected word line WL_{AN}, grounding the other word lines WL_{AN-1} and WL_{AN+1}, and floating all bit lines BL_{N-1}, BL_{N-1}, and BL_{N+1}, the first non-volatile memory transistors T_{AN-1N}, T_{ANN}, and T_{AN+1N} coupled to the selected word line WL_{AN} may be erased.

Next, the erasing operation of the second non-volatile memory transistor of the selected unit memory cell M is described in detail. The erasing of the second non-volatile memory transistor may be performed by the Fowler-Nordheim tunneling method. The back bias voltage VB applied to the bulk region of the semiconductor substrate 1 may be about 11 V. The voltages applied to the respective lines are shown in Table 4. However, the applied voltages are exemplary and example embodiments are not limited thereto.

TABLE 4

| BL_{N-1} | CSL_{N-1} | WL_{AN-1} | SL_{N-1} | WL_{BN-1} |
|---|---|---|---|---|
| 5 V | Floating | — | Ground | — |
| BL_{N} | CSL_{N} | WL_{AN} | SL_{N} | WL_{BN} |
| Floating | Floating | −5 V | 5 V | −5 V |
| BL_{N+1} | CSL_{N+1} | WL_{AN+1} | SL_{N+1} | WL_{BN+1} |
| 5 V | Floating | — | Ground | — |

Referring to Table 4, both of the common source line CSL_{N} and the bit line BL_{N} may be floated, and an erasing voltage, e.g., about (−5) V, may be applied to the word line WL_{BN}. A voltage, e.g., about 5 V, may be applied to the selection line SL_{N} to prevent the gate insulation layer of the selection transistor T_{S} from being damaged by the voltage difference between the back bias voltage VB and the selection lines SL.

For non-selected unit memory cells, the common source lines CSL_{N-1} and CSL_{N+1} coupled to the non-selected unit memory cells may be floated. A voltage, e.g., about 5 V, may be applied to the bit lines BL_{N-1} and BL_{N+1}. Also, a voltage of about 5 V may be applied to the word lines WL_{AN-1}, WL_{BN-1}, WL_{AN}, WL_{AN+1}, and WL_{BN+1}. A voltage of about 5 V may be applied to the selection lines SL_{N-1} and SL_{N+1}, or the selection lines SL_{N-1} and SL_{N+1} may be grounded.

In example embodiments, as described above with reference to Table 3, an erasing voltage, e.g., about (−5) V, may be applied to the word lines WL_{BN-1} WL_{BN}, WL_{BN+1} connected to the second non-volatile memory transistors T_{BN-1N-1}, . . . , T_{BNN}, . . . , T_{BN+1N+1}, these second non-volatile memory transistors T_{BN-1N-1}, . . . , T_{BNN}, . . . , T_{BN+1N+1}, sharing the well, may be erased by block. Alternatively, by applying the erasing voltage, e.g., of about (−5.) V, only to the selected word line WL_{BN} and not applying the erasing voltage to the other word lines WL_{AN-1} and WL_{AN+1}, the erasing operation of the second non-volatile memory transistors T_{BN-1N}, . . . , T_{BNN}, . . . , T_{BN+1N} may be performed by page. Also, in another example embodiment, by applying the erasing voltage to all word lines WL_{AN-1}, WL_{BN-1}, WL_{AN}, WL_{BN}, WL_{AN+1}, and WL_{BN+1}, all non-volatile memory transistors T_{AN-1N-1}, . . . , T_{ANN}, . . . , T_{AN+1N+1}; T_{BN-1N-1}, . . . , T_{BNN}, . . . , T_{BN+1N+1} may be erased.

Reading Operation

The reading operation of the non-volatile memory device 200 in FIG. 3 is described below. For example, the reading operation of the unit memory cell M indicated by a dotted line among the unit memory cells arranged in the row and column matrix format is described.

The reading operation of the first or second non-volatile memory transistor T_{ANN} and T_{BNN} of the selected unit memory cell M may be performed by detecting a change in a threshold voltage according to existence of data bit. The voltages applied to the respective lines for the reading operation of the first or second non-volatile memory transistor T_{ANN} and T_{BNN} are shown in Tables 5 and 6. However, the applied voltages are exemplary and example embodiments are not limited thereto.

TABLE 5

| BL_{N-1} | CSL_{N-1} | WL_{AN-1} | SL_{N-1} | WL_{BN-1} |
|---|---|---|---|---|
| Floating | Ground | Ground | Ground | — |
| BL_{N} | CSL_{N} | WL_{AN} | SL_{N} | WL_{BN} |
| Ground | 0.5 V | V_{CC} | Ground | Floating |
| BL_{N+1} | CSL_{N+1} | WL_{AN+1} | SL_{N+1} | WL_{BN+1} |
| Floating | Ground | Ground | Ground | — |

Referring to Table 5, to read the first non-volatile memory transistor T_{ANN}, a voltage of about 0.5 V may be applied to the common source line CSL_{N}, and the bit line BL_{N} may be grounded. A read voltage V_{CC}, e.g., about 2 V, may be applied to the word line WL_{AN}. In this case, the selection line SL_{N} may be grounded to turn off the selection transistor T_{SNN}. For non-selected unit memory cells, the common source lines CSL_{N-1} and CSL_{N+1} coupled to the non-selected unit memory cells may be grounded and the bit lines BL_{N-1} and BL_{N+1} may be floated.

TABLE 6

| BL_{N-1} | CSL_{N-1} | WL_{AN-1} | SL_{N-1} | WL_{BN-1} |
|---|---|---|---|---|
| Floating | Ground | Ground | Ground | Ground |
| BL_{N} | CSL_{N} | WL_{AN} | SL_{N} | WL_{BN} |
| Ground | 0.5 V | Ground | V_{CC} | V_{CC} |
| BL_{N+1} | CSL_{N+1} | WL_{AN+1} | SL_{N+1} | WL_{BN+1} |
| Floating | Ground | Ground | Ground | Ground |

Referring to Table 6, for the reading operation of the selected second non-volatile memory transistor T_{BNN}, a voltage of about 0.5 V may be applied to the common source line CSL_{N}, and the bit line BL_{N} may be grounded. While voltage, e.g., about 2 V, may be applied to the selection line SL_{N} to turn on the selection transistor T_{SNN}, read voltage V_{CC}, e.g., about 2 V, may be applied to the word line WL_{BN}, thereby detecting current. For non-selected unit memory cells, the common source lines CSL_{N-1} and CSL_{N+1} coupled to the non-selected unit memory cells may be grounded and the bit lines BL_{N-1} and BL_{N+1} may be floated.

For example, a method of driving the non-volatile memory device 200 including a memory cell array with a plurality of unit memory cells M arranged in form of a matrix of rows and columns, each of the unit memory cells M including, e.g., the first and second non-volatile memory transistors T_{ANN} and T_{BNN} sharing the common source CS and a selection transistor T_{SNN} connected between the common source CS and any one of the first and second non-volatile memory transistors T_{ANN} and T_{BNN}, the method including selecting at least one of the first and second non-volatile memory transistors T_{ANN} and T_{BNN} and programming the selected at least one non-volatile memory transistor, selecting at least one of the first and second non-volatile memory transistors T_{ANN} and T_{BNN} and reading the selected at least one non-volatile memory transistor, and selecting the at least one of the first and second non-volatile memory transistors T_{ANN} and T_{BNN} and erasing the selected at least one non-volatile memory transistor. For example, any one of the first and second non-volatile memory transistors T_{ANN} and T_{BNN} may be operated in a NOR type method, and the other one of the first and second non-volatile memory transistors T_{ANN} and T_{BNN} may be operated in a NAND type method. In other words, the first and second non-volatile memory transistors T_{ANN} and T_{BNN} may be operated via different methods among NOR and NAND type methods.

The programming of the selected non-volatile memory transistor may include applying a program voltage to a word line coupled to a control gate of the selected non-volatile memory transistor of the first and second non-volatile memory transistors T_{ANN} and T_{BNN} that are continuously arranged in a column direction of the memory cell array, and applying a turn-off voltage to a selection line coupled to gate of selection transistor T_{SNN} connected to the selected non-volatile memory transistor of the selection transistors that are continuously arranged in the column direction of the memory cell array.

The erasing of the selected non-volatile memory transistor may include applying an erasing voltage to a word line coupled to a control gate of the selected non-volatile memory transistor of the first and second non-volatile memory transistors T_{ANN} and T_{BNN} that are continuously arranged in a column direction of the memory cell array, and applying a voltage to compensate the erasing voltage to a bit line coupled to drains of non-selected non-volatile memory transistors coupled to the word line. For example, erasing of the selected non-volatile memory transistor may be performed by block or page.

As described above, according to example embodiments, a 1-T NOR transistor and a 1-T NAND transistor may be integrated into a single unit memory cell, so that the operation speed and lift span of each of the non-volatile memory transistors may be improved. Also, since peripheral circuits, e.g., a sense amplifier and a decoder may be shared for the operation of integrated memory cells, SOCs, e.g., SIMs, smart cards, and electronic passports, may be easily manufactured at high density. Furthermore, since a selection transistor may be asymmetrically included in the unit memory cell, malfunction, e.g., a programming or erasing operation of a non-selected transistor due to a voltage difference between source and drain of the transistors, may be prevented.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A non-volatile memory device, comprising:
a memory cell array with a plurality of unit memory cells, the unit memory cells being arranged in a matrix pattern of rows and columns, each of the unit memory cells including:
a first impurity diffusion region and a second impurity diffusion region in an active region of a semiconductor substrate,
first and second memory gates on the active region between the first impurity diffusion region and the second impurity diffusion region, the first and second memory gates corresponding to respective first and second memory transistors, and each of the first and second memory gates is adjacent to a respective one of the first and second impurity diffusion regions,
one select gate on the active region between the first and second memory gates, the select gate corresponding to a select transistor;
a third impurity diffusion region in the active region between the select gate and one of the first and second memory gates, and
a common source region in the active region between the select gate and the other one of the first and second memory gates;
a first word line coupled to control gates of the first memory transistors arranged in a column direction of the memory cell array;
a second word line coupled to control gates of the second memory transistors arranged in the column direction of the memory cell array;
a selection line coupled to gates of the selection transistors arranged in the column direction of the memory cell array; and
bit lines coupled to the first and second impurity diffusion regions.

2. The non-volatile memory device as claimed in claim 1, wherein the first and second memory transistors are programmed in different ways from each other.

3. The non-volatile memory device as claimed in claim 1, wherein one of the first and second memory transistors is a NOR type transistor, and the other one of the first and second memory transistors is a NAND type transistor.

4. The non-volatile memory device as claimed in claim 3, wherein the selection transistor is on the active region between the NAND type transistor and the common source region.

5. The non-volatile memory device as claimed in claim 3, wherein the NOR type transistor is programmed by Hot-carrier Injection (HCI) and the NAND type transistor is programmed by F-N (Flowler-Nordheim) tunneling.

6. (canceled)

7. The non-volatile memory device as claimed in claim 1, wherein at least one of the first and second memory transistors includes a first insulation layer, a charge storage layer, and a second insulation layer, and
wherein the first insulation layer, the charge storage layer, and the second insulation layer are sequentially stacked between a semiconductor substrate on which the memory cell array is formed and the control gates of the first and second memory transistors.

8. The non-volatile memory device as claimed in claim 7, wherein the charge storage layer includes a floating conductive layer or a charge trap type insulation layer.

9. The non-volatile memory device as claimed in claim 7, wherein at least one of the first and second insulation layers includes a high dielectric thin layer.

10. (canceled)

11. The non-volatile memory device as claimed in claim 1, further comprising:
first and second word lines connected to the first and second memory gates, respectively;
a select line connected to the select gate; and
first and second bit lines connected to the first and second impurity diffusion regions, respectively.

12. A nonvolatile memory device having a plurality of memory cell units, the memory cell unit comprising:
a first impurity diffusion region and a second impurity diffusion region in an active region of a semiconductor substrate;
first and second memory gates on the active region between the first impurity diffusion region and the second impurity diffusion region, the first and second memory gates each respectively adjacent to the first and second impurity diffusion regions;
one select gate on the active region between the first and second memory gates; and
first and second floating diffusion regions in the active region between the select gate and a corresponding one of the first and second memory gates,
wherein the first memory gate, the second memory gate, and the select gate correspond to a first memory transistor, a second memory transistor, and a select transistor, respectively, and
wherein the first memory transistor is configured to perform a first program operation performed by F-N (Flowler-Nordheim) tunneling, and the second memory transistor is configured to perform a second program operation by Hot-carrier Injection (HCI).
